(19) United States
(12) Patent Application Publication
(10) Pub. No.: US 2013/0063884 A1
(43) Pub. Date: Mar. 14, 2013

(54) CONFIGURABLE DEVICE SUPPORTS

(71) Applicants: Avi R. Geiger, Seattle, WA (US); Andrew W. Hill, Redmond, WA (US)

(72) Inventors: Avi R. Geiger, Seattle, WA (US); Andrew W. Hill, Redmond, WA (US)

(73) Assignee: MICROSOFT CORPORATION, Redmond, WA (US)

(21) Appl. No.: 13/232,238

(22) Filed: Sep. 14, 2011

(51) Int. Cl. H05K 7/00

(52) U.S. Cl. 361/679.21

(57) ABSTRACT

In embodiments of configurable device supports, a computing device includes a housing structure that supports an integrated display, and the housing structure is configurable in multiple positions to position the display for viewing. The computing device also includes configurable device supports that are integrated with the housing structure to support the computing device when placed on a surface. The configurable device supports are configurable as one of slideable or slide resistant.

### BACKGROUND

Various types of computing and media devices, such as desktop computers, portable computing devices, televisions, and display devices, are increasingly designed with a touch-screen display for user input and touch interaction. The various types of devices are also designed for multi-position display, and can be used in an upright position as a vertical display, or used flat on a table as a horizontal display. However, some devices may not be stable or resistant to inadvertent sliding, such as when a user interacts with the touch surface of a touch-screen display on a tablet computer that slides on a table surface. Many devices are configured with sticky rubber pads (commonly referred to as “feet”) that hold a device in place on a surface, while other types of devices without any sort of supports or pads tend to slide on a surface, such as when a user is interacting with a touch-screen of a device.

### SUMMARY

This Summary introduces simplified concepts of configurable device supports, and the concepts are further described below in the Detailed Description and/or shown in the Figures. This Summary should not be considered to describe essential features of the claimed subject matter, nor used to determine or limit the scope of the claimed subject matter.

Configurable device supports are described. In embodiments, a computing device includes a housing structure that supports an integrated display, and the housing structure is configurable in multiple positions to position the display for viewing. The computing device also includes configurable device supports that are integrated with the housing structure to support the computing device when placed on a surface. The configurable device supports are configurable as one of slideable or slide resistant and/or can be based on a position of the integrated display.

In other embodiments, the configurable device supports can be configured slide resistant based on a vertical display position of the integrated display, or configured slideable based on a horizontal display position of the integrated display. The configurable device supports can be mechanically or electrically actuated to change shape or contact with the surface to be either slideable or slide resistant. In an implementation, the configurable device supports can be slideable when configured convex relative to a surface, or implemented slide resistant when configured concave relative to the surface. The configurable device supports may also have one or more material properties that are modifiable to configure the device supports as either slideable or slide resistant.

In other embodiments, the configurable device supports can include first device supports that are slideable and also include second device supports that are slide resistant, where the first and second device supports are implemented to switch to position either the first or second device supports in contact with a surface. The computing device can also include a device service that is implemented to activate a configuration of the configurable device supports as either slideable or slide resistant. The device service can also receive a user-selectable input to change the configuration of the configurable device supports, such as from slideable to slide resistant, or vice-versa.

### BRIEF DESCRIPTION OF THE DRAWINGS

Embodiments of configurable device supports are described with reference to the following Figures. The same numbers may be used throughout to reference like features and components that are shown in the Figures:

FIG. 1 illustrates examples of configurable device supports in accordance with one or more embodiments.

FIG. 2 further illustrates examples of configurable device supports in accordance with one or more embodiments.

FIG. 3 illustrates example method(s) of configurable device supports in accordance with one or more embodiments.

FIG. 4 illustrates various components of an example electronic device in which embodiments of configurable device supports can be implemented.

### DETAILED DESCRIPTION

Embodiments of configurable device supports are described. As noted above, some user devices may not be stable or resistant to inadvertent sliding, such as when a user interacts with a touch-screen display on a tablet computer that slides on a table surface. Alternatively, there may be times when the user wants the device to be slideable, such as to slide the device across a table or desktop surface so that another person can view the display. In embodiments, a computing device can be implemented to include configurable device supports that are integrated with a housing structure of the device to support the computing device when placed on a surface. The configurable device supports are configurable as one of slideable or slide resistant and/or can be based on a position of the integrated display, based on user interaction with the device, and/or based on other device uses. For example, a touch-screen display or monitor may be configurable in multiple display and use positions, and different display positions can each have a different requirement for resistance to sliding on a surface, such as based on different forces that are expected with user interaction on the display.

While features and concepts of configurable device supports can be implemented in any number of different devices, systems, and/or configurations, embodiments of configurable device supports are described in the context of the following example devices, systems, and methods.

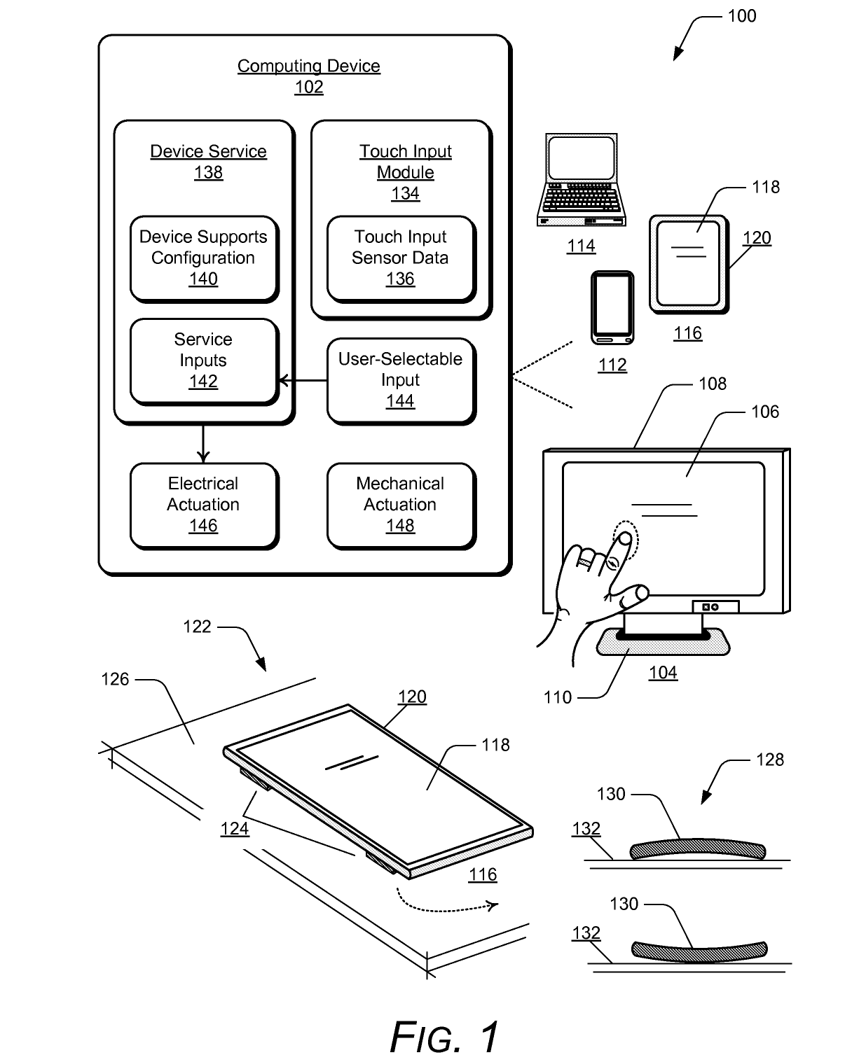

FIG. 1 illustrates an example system 100 in which embodiments of configurable device supports can be implemented. The example system 100 includes a computing device 102, which may be any one or combination of a fixed or mobile device, in any form of a consumer, computer, portable, communication, navigation, media playback, entertainment, gaming, tablet, display, and/or electronic device. For example, the computing device 102 can be implemented as a touch-screen display device 104, such as an all-in-one computing device or surface table computing device that includes a touch-screen display 106. In this example, the touch-screen display is supported in a housing structure 108 of the device, and the device includes a configurable device support 110 that is integrated with the housing structure to support the touch-screen display device when placed on a surface.

The touch-screen display device may be configurable in multiple display orientations, such as in an upright, vertical display orientation or in a flat, horizontal display orientation. A touch-screen display device may also be utilized with a computer, television client device, and/or gaming system that is connected to the display device to display media content. In embodiments, the configurable device supports of a computing device can be configured slide resistant based on a vertical display position of the display device, or the configurable device supports can be configured slideable based on a horizontal display position of the display device. The configuration of the device supports can also be user-selectable as slideable or slide resistant based on user preference.

The computing device 102 may also be any type of portable computing device, such as a mobile phone 112, portable computer 114, or tablet computer 116 that includes an integrated, touch-screen display 118. The touch-screen display is supported in a housing structure 120 of the device, and the device (also shown at 122) includes configurable device supports 124 that are integrated with the housing structure to support the tablet computer when placed on a surface 126, such as a table or desktop. In embodiments, the configurable device supports of a computing device are configurable to be slideable or slide resistant. For example, a user of the tablet computer 116 may prefer that the device is slide resistant while the user interacts with the touch-screen display 118 when the device is placed on a table or desktop surface. At other times, the user may want the device to be slideable, such as to slide the device across the table or desktop surface so that another person can view the display or use the device.

In embodiments, the configurable device supports of a computing device, such as the configurable device supports 124 of the tablet computer 116, can be slideable when configured convex relative to a surface, or slide resistant when configured concave relative to the surface. In the example shown at 128, a configurable device support 130 is slide resistant when configured concave relative to a surface 132 (e.g., similar to how a suction cup would be slide resistant). The same configurable device support 130 can also be slideable when configured convex relative to the surface 132 (e.g., a smaller contact area of the configurable device support can be easily slideable on the surface).

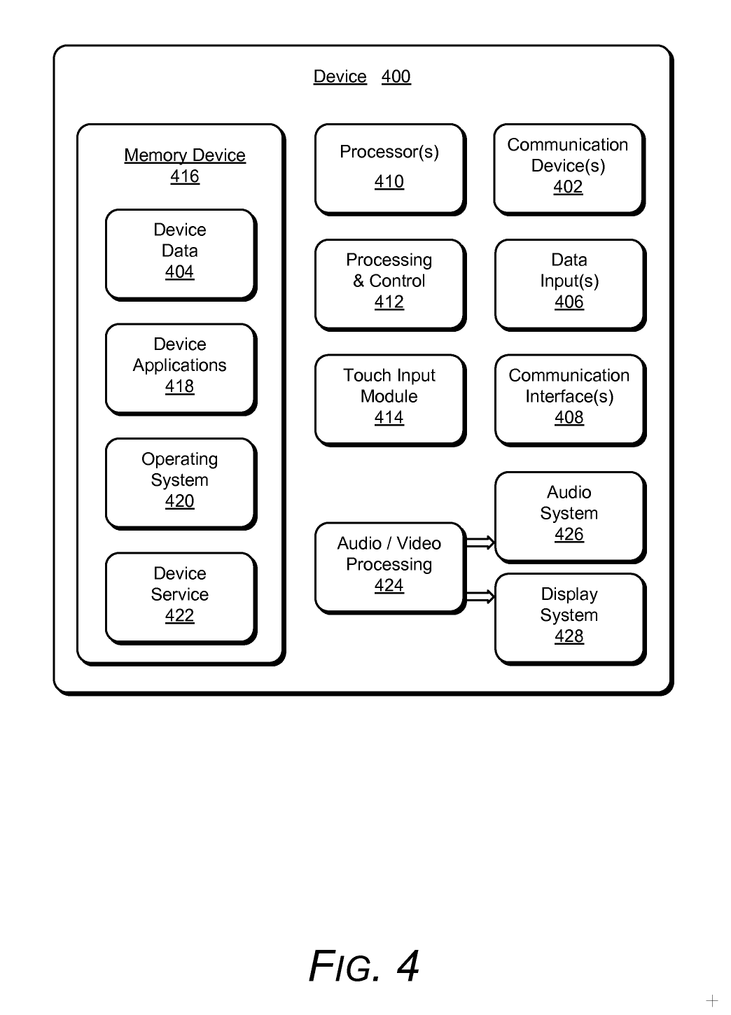

A touch-screen display of a computing device is implemented to sense touch and gesture inputs on the touch surface, such as user-initiated touch and/or selector inputs in a user interface that is displayed on the touch-screen display. In implementations, the computing device 102 includes a touch input module 134 that recognizes touch input sensor data 136, such as a user touch interaction on a touch-screen display. Additionally, any of the computing devices can be implemented with various components, such as one or more processors and memory devices, as well as with any combination of differing components as further described with reference to the example electronic device shown in FIG. 4.

In this example, the computing device 102 includes a device service 138 that can be implemented as computer-executable instructions, such as a software application or module that is executed by one or more processors to implement the various embodiments described herein. The device service can be implemented to control the configuration 140 of the configurable device supports for the computing device 102. The device service 138 is also implemented to receive various service inputs 142, such as from components, sensors, and/or software on the computing device. The device service can also receive a user-selectable input 144 to change the configuration 140 of the configurable device supports for a computing device, such as from slideable to slide resistant.

In embodiments, the device service 138 at the computing device 102 can be implemented to control electrical actuation 146 of the configurable device supports to change the shape or contact with a surface to be either slideable or slide resistant. For example, an electrical input can modify one or more material properties of the configurable device supports, such as to increase a friction consistency, material phase change, or to change the shape of a device support. In one example, the configurable device support 130 shown at 128 may be configured either concave or convex relative to the surface 132 based on electrical input. Alternatively or in addition to the electrical actuation 146, the computing device 102 can be implemented for mechanical actuation 148 of the configurable device supports, such as with a hinge and/or mechanical links to change the shape or contact with a surface to be either slideable or slide resistant. For example, a first set of device supports that are slideable can be mechanically or electrically actuated to switch with a second set of device supports that are slide resistant, so that either the first or second set of device supports are in contact with a surface.

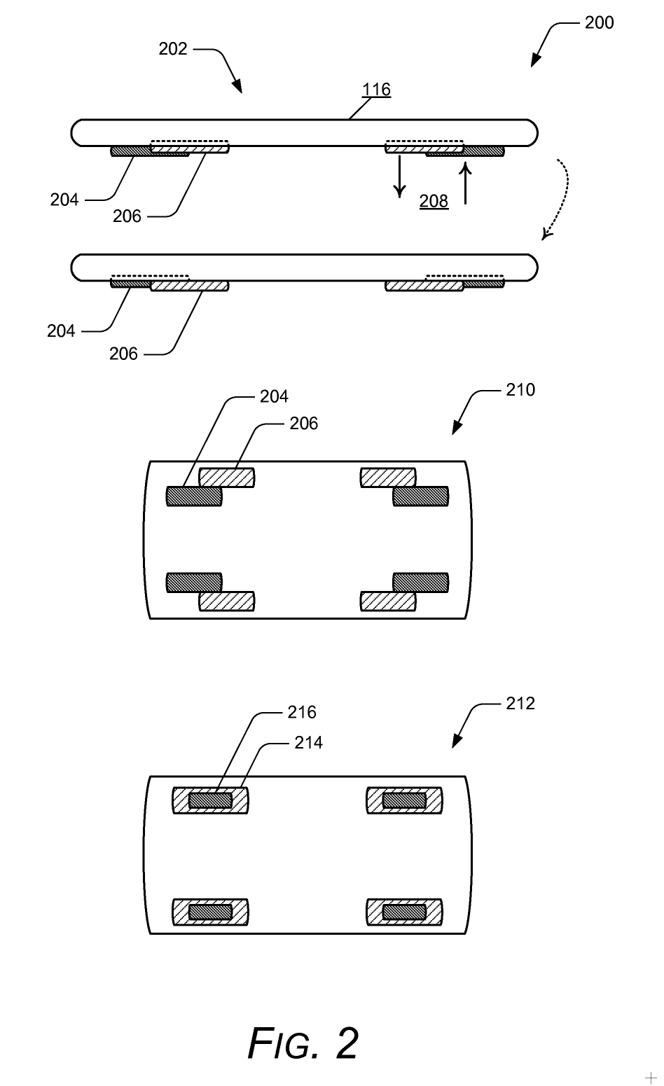

FIG. 2 further illustrates examples 200 of configurable device supports, such as described with reference to the tablet computer 116 shown in FIG. 1. The tablet computer is shown in a side view at 202, and includes a first set of configurable device supports 204 that are slide resistant, and a second set of configurable device supports 206 that are slideable. The first and/or second set of configurable device supports can be mechanically or electrically actuated to switch positions as shown at 208 so that either the first or second set of configurable device supports are in contact with a surface. In this example, the first set of configurable device supports 204 are initially positioned to contact a surface, such as when the device is placed on a table or desktop. Then, the second set of configurable device supports 206 are positioned to contact the surface.

The tablet computer 116 is shown from a bottom view at 210 to illustrate example placement of the first and second sets of configurable device supports integrated in the housing structure of the device. In implementations, both of the first and second sets of configurable device supports can be configured to actuate, or only one of the first or second sets of configurable device supports can be configured to actuate while the other remains fixed. For example, the second set of configurable device supports 206 may raise and lower relative to the first set of configurable device supports 204 that remain fixed to the housing structure of the device. An alternate example of first and second sets of configurable device supports is shown at 212, where a first set of configurable device supports 214 are slide resistant and configurable to extend out from a second set of configurable device supports 216 that are slideable.

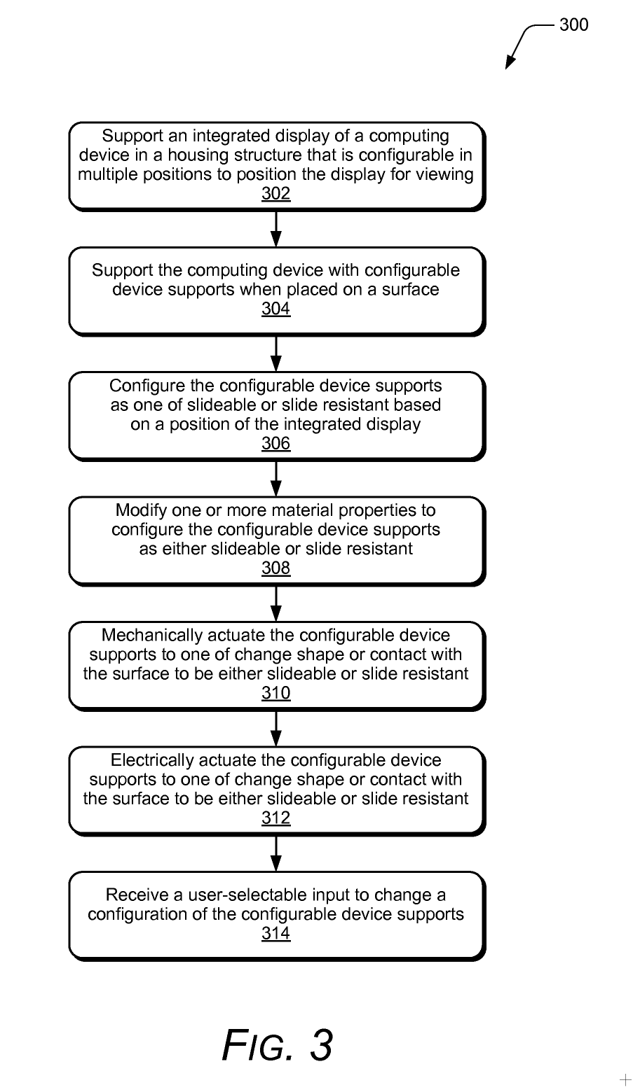

Example method 300 is described with reference to FIG. 3 in accordance with one or more embodiments of configurable device supports. Generally, any of the services, functions, methods, procedures, components, and modules described herein can be implemented using software, firmware, hardware (e.g., fixed logic circuitry), manual processing, or any combination thereof. A software implementation represents program code that performs specified tasks when executed by a computer processor. The example methods may be described in the general context of computer-executable instructions, which can include software, applications, routines, programs, objects, components, data structures, procedures, modules, functions, and the like. The program code can be stored in one or more computer-readable storage media devices, both local and/or remote to a computer processor. The methods may also be practiced in a distributed computing environment by multiple computer devices. Further, the features described herein are platform-independent and can be implemented on a variety of computing platforms having a variety of processors.

FIG. 3 illustrates example method(s) 300 of configurable device supports. The order in which the method blocks are described are not intended to be construed as a limitation, and any number of the described method blocks can be combined in any order to implement a method, or an alternate method.

At block 302, an integrated display of a computing device is supported in a housing structure that is configurable in multiple positions to position the display for viewing. For example, the touch-screen display device 104 (FIG. 1) includes the touch-screen display 106 that is supported in the housing structure 108 of the device. Similarly, the tablet computer 116 includes an integrated, touch-screen display 118 that is supported in the housing structure 120 of the device.

At block 304, the computing device is supported with configurable device supports when placed on a surface. For example, the touch-screen display device 104 includes the configurable device support 110 that is integrated with the housing structure 108 of the device to support the touch-screen display device when placed on a surface, such as a table or desktop. Similarly, the tablet computer 116 includes the configurable device supports 124 that are integrated with the housing structure 120 of the device to support the tablet computer when placed on the surface 126.

At block 306, the configurable device supports are configured as one of slideable or slide resistant based on a position of the integrated display. For example, the configurable device support 110 of the touch-screen display device 104 can be configured slide resistant based on a vertical display position of the display device, or the configurable device support can be configured slideable based on a horizontal display position of the display device. In embodiments, the configurable device supports of a computing device are configured convex and slideable relative to the surface, or concave and slide resistant relative to the surface. The configurable device supports can also include first device supports that are slideable and second device supports that are slide resistant, and then either the first device supports or the second device supports are positioned in contact with the surface.

At block 308, one or more material properties are modified to configure the configurable device supports as either slideable or slide resistant. For example, an electrical input can modify one or more material properties of the configurable device supports 124, such as to increase a friction consistency or to change the shape of a device support. In the example shown at 128 (FIG. 1), the configurable device support 130 may be configured either concave or convex relative to the surface 132 based on electrical input.

At block 310, the configurable device supports are mechanically actuated to one of change shape or contact with the surface to be either slideable or slide resistant. At block 312, the configurable device supports are electrically actuated to one of change the shape or contact with the surface to be either slideable or slide resistant. For example, the computing device 102 is implemented for electrical actuation 146 and/or mechanical actuation 148 of the configurable device supports to change the shape or contact with a surface to be either slideable or slide resistant.

At block 314, a user-selectable input is received to change a configuration of the configurable device supports. For example, the computing device 102 includes the device service 138 that receives a user-selectable input 144, and initiates changing the configuration 140 of the configurable device supports, such as from slideable to slide-resistant, or vice-versa.

FIG. 4 illustrates various components of an example device 400 that can be implemented as any of the devices, or services implemented by the devices, described with reference to the previous FIGS. 1-3. In embodiments, the device may be implemented as any one or combination of a fixed or mobile device, in any form of a consumer, computer, portable, user, communication, phone, navigation, television, appliance, gaming, media playback, and/or electronic device. The device may also be associated with a user (i.e., a person) and/or an entity that operates the device such that a device describes logical devices that include users, software, firmware, hardware, and/or a combination of devices.

The device 400 includes communication devices 402 that enable wired and/or wireless communication of device data 404, such as received data, data that is being received, data scheduled for broadcast, data packets of the data, etc. The device data or other device content can include configuration settings of the device, media content stored on the device, and/or information associated with a user of the device. Media content stored on the device can include any type of audio, video, and/or image data. The device includes one or more data inputs 406 via which any type of data, media content, and/or inputs can be received, such as user-selectable inputs and any other type of audio, video, and/or image data received from any content and/or data source.

The device 400 also includes communication interfaces 408, such as any one or more of a serial, parallel, network, or wireless interface. The communication interfaces provide a connection and/or communication links between the device and a communication network by which other electronic, computing, and communication devices communicate data with the device.

The device 400 includes one or more processors 410 (e.g., any of microprocessors, controllers, and the like) which process various computer-executable instructions. Alternatively or in addition, the device can be implemented with any one or combination of software, hardware, firmware, or fixed logic circuitry that is implemented in connection with processing and control circuits which are generally identified at 412. In embodiments, the device 400 can also include a touch input module 414 that is implemented to recognize touch input sensor data. Although not shown, the device can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures.

The device 400 also includes one or more memory devices 416 (e.g., computer-readable storage media) that enable data storage, such as random access memory (RAM), non-volatile memory (e.g., read-only memory (ROM), flash memory, etc.), and a disk storage device. A disk storage device may be implemented as any type of magnetic or optical storage device, such as a hard disk drive, a recordable and/or rewriteable disc, and the like. The device may also include a mass storage media device.

Computer readable media can be any available medium or media that is accessed by a computing device. By way of example, and not limitation, computer readable media may comprise storage media and communication media. Storage media include volatile and non-volatile, removable and non-removable media implemented in any method or technology for storage of information, such as computer-readable instructions, data structures, program modules, or other data. Storage media include, but are not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store information and which can be accessed by a computer.

Communication media typically embody computer-readable instructions, data structures, program modules, or other data in a modulated data signal, such as carrier wave or other transport mechanism. Communication media also include any information delivery media. A modulated data signal has one or more of its characteristics set or changed in such a manner as to encode information in the signal. By way of example, and not limitation, communication media include wired media such as a wired network or direct-wired connection, and wireless media such as acoustic, RF, infrared, and other wireless media.

A memory device 416 provides data storage mechanisms to store the device data 404, other types of information and/or data, and various device applications 418. For example, an operating system 420 can be maintained as a software application with the memory device and executed on the processors. The device applications may also include a device manager, such as any form of a control application, software application, signal processing and control module, code that is native to a particular device, a hardware abstraction layer for a particular device, and so on. In this example, the device applications 418 include a device service 422 that implements embodiments of configurable device supports as described herein.

The device 400 also includes an audio and/or video processing system 424 that generates audio data for an audio system 426 and/or generates display data for a display system 428, such as an integrated touch-screen display. The audio system and/or the display system may include any devices that process, display, and/or otherwise render audio, video, display, and/or image data. Display data and audio signals can be communicated to an audio device and/or to a display device via an RF (radio frequency) link, S-video link, composite video link, component video link, DVI (digital video interface), analog audio connection, or other similar communication link. In implementations, the audio system and/or the display system are integrated components of the example device. Alternatively, the audio system and/or the display system are external components to the device.

Although embodiments of configurable device supports have been described in language specific to features and/or methods, the subject of the appended claims is not necessarily limited to the specific features or methods described. Rather, the specific features and methods are disclosed as example implementations of configurable device supports.

1. A computing device, comprising:
a housing structure configured to support an integrated display, the housing structure configurable in multiple positions to position the display for viewing; and
configurable device supports integrated with the housing structure to support the computing device when placed on a surface, the configurable device supports being configurable as one of slideable or slide resistant.

2. A computing device as recited in claim 1, wherein the configurable device supports are configured slide resistant based on a vertical display position of the integrated display.

3. A computing device as recited in claim 1, wherein the configurable device supports are configured slideable based on a horizontal display position of the integrated display.

4. A computing device as recited in claim 1, wherein the configurable device supports are mechanically actuated to one of change shape or contact with the surface to be either slideable or slide resistant.

5. A computing device as recited in claim 1, wherein the configurable device supports are electrically actuated to one of change shape or contact with the surface to be either slideable or slide resistant.

6. A computing device as recited in claim 1, wherein the configurable device supports are one of slideable when configured convex relative to the surface, or slide resistant when configured concave relative to the surface.

7. A computing device as recited in claim 1, wherein the configurable device supports include first device supports that are slideable, and include second device supports that are slide resistant, and wherein the first and second device supports are configured to switch to position one of the first or second device supports in contact with the surface.

8. A computing device as recited in claim 1, wherein the configurable device supports have one or more material properties that are modifiable to configure the configurable device supports as either slideable or slide resistant.

9. A computing device as recited in claim 1, further comprising a memory and a processor to implement a device service that is configured to activate a configuration of the configurable device supports as said one of slideable or slide resistant.

10. A computing device as recited in claim 1, wherein the device service is configured to receive a user-selectable input to change the configuration of the configurable device supports.

11. A method, comprising:
supporting an integrated display of a computing device in a housing structure that is configurable in multiple positions to position the integrated display for viewing;
supporting the computing device with configurable device supports when placed on a surface; and
configuring the configurable device supports as one of slideable or slide resistant based on a position of the integrated display.

12. A method as recited in claim 11, wherein the configurable device supports are configured slide resistant based on a vertical display position of the integrated display.

13. A method as recited in claim 11, wherein the configurable device supports are configured slideable based on a horizontal display position of the integrated display.

14. A method as recited in claim 11, further comprising mechanically-actuating the configurable device supports to one of change shape or contact with the surface to be either slideable or slide resistant.

15. A method as recited in claim 11, further comprising electrically-actuating the configurable device supports to one of change shape or contact with the surface to be either slideable or slide resistant.

16. A method as recited in claim 11, wherein the configurable device supports are configured one of convex and slideable relative to the surface, or concave and slide resistant relative to the surface.

17. A method as recited in claim 11, further comprising positioning one of first device supports or second device supports in contact with the surface, the configurable device supports including the first and second device supports, and wherein the first device supports are slideable and the second device supports are slide resistant.

18. A method as recited in claim 11, further comprising modifying one or more material properties to configure the configurable device supports as either slideable or slide resistant.

19. A method as recited in claim 11, further comprising receiving a user-selectable input to change a configuration of the configurable device supports.

20. A configurable device support system, comprising:
configurable device supports integrated in a computing device to support the computing device when placed on a surface, the configurable device supports being configurable as one of slideable or slide resistant based on a position of an integrated display of the computing device; and
a device service executable by a processor and configured to activate a configuration of the configurable device supports as said one of slideable or slide resistant.
